(19) United States
(12) Patent Application Publication
(10) Pub. No.: US 2015/0068797 A1
(43) Pub. Date: Mar. 12, 2015

(54) ELECTROMAGNETIC FREQUENCY RADIATION FOR NON-IONIZING RADIATION HARMONIZER AND METHOD OF USE

(71) Applicant: Rhoda Alale, Wilmington, OH (US)

(72) Inventor: Rhoda Alale, Wilmington, OH (US)

(21) Appl. No.: 14/025,565

(22) Filed: Sep. 12, 2013

(51) Int. Cl. H05K 9/00

(52) U.S. Cl. CPC H05K 9/00
USPC 174/377; 29/602.1

(57) ABSTRACT

An electromagnetic frequency and non-ionizing radiation harmonizer that may be a film, a sheet or a textile that harmonizes or mitigates electromagnetic frequency radiation from non-ionizing EMF emitting devices while allowing an integration of vibrations or frequency mediums. The harmonizer includes a method of utilizing an electromagnetic frequency radiation and non-ionizing radiation harmonizer that includes the steps of obtaining a film, a sheet or a textile that harmonizes or mitigates electromagnetic frequency radiation from one or more non-ionizing EMF emitting devices and disposing the film, sheet or textile in direct contact or within dose proximity of one or more non-ionizing EMF emitting devices.

This application claims priority to U.S. Provisional Application 61/262,149 filed on Nov. 18, 2009, the entire disclosure of which is incorporated by reference. The present application is a Continuation-In-Part application to U.S. Non-Provisional application Ser. No. 12/949,519 filed on Nov. 18, 2010, the entire disclosure of which is incorporated by reference.

### TECHNICAL FIELD & BACKGROUND

Research directly shows a correlation of electromagnetic frequency radiation or EMF from electronics and power transformers such as cell phones, wireless fidelity or IEEE 802.11 b wireless networking or wireless fidelity or WIFI related devices, computers and appliances and to diseases such as acoustic neuroma or hearing loss, autism, fibromyalgia and others, prompting two new classes of diagnoses, electromagnetic hypersensitivity or EHS and multiple chemical sensitivity or MCS, Prominent cellular and biomedical engineers agree that sustained exposure to EMF radiation causing EHS and MCS may contribute to causing autism and other diseases. Additionally, homes built in geographic areas where radioactive chemicals may be in the ground may be relatively more at risk for having high levels of electromagnetic static radiation in the electrical currents of the homes in those geographic areas.

The present invention generally relates to a radiation harmonizer. More specifically, the invention is an electromagnetic frequency radiation for non-ionizing radiation harmonizer in various sheet, film and textile forms.

It is an object of the invention to provide an electromagnetic frequency radiation for non-ionizing radiation harmonizer that causes the electrons of EMF radiation to spin forward allowing the EMF radiation to be in natural harmony with the biorhythm of healthy cells of a person's body.

It is an object of the invention to provide an electromagnetic frequency radiation for non-ionizing radiation harmonizer that allows for harmonization or mitigation of EMF radiation in non-ionizing EMF energized electronic devices and appliances such as cell phones, household appliances, energized machinery, electrical wall currents, medical technology devices, lamps, fuse boxes, WIFI related devices, televisions, medical electrical devices, automotive electric devices, telecommunications devices and electronic components in aircraft.

It is an object of the invention to provide multiple electromagnetic frequency radiation for non-ionizing radiation harmonizers that may be utilized for harmonizing or clearing static electromagnetic frequency radiation.

It is an object of the invention to provide a multiple electromagnetic frequency radiation for non-ionizing radiation harmonizer that rebalances kinetic energy in the cells of a person's body.

What is really needed is a multiple electromagnetic frequency radiation for a non-ionizing radiation harmonizer that causes the electrons of EMF radiation to spin forward allowing the EMF radiation to be in natural harmony with the biorhythm of healthy cells of a body exposed to the EMF radiation, that allows for harmonization or mitigation of EMF radiation in non-ionizing EMF energized electronic devices and appliances such as cell phones, household appliances, energized machinery, electrical wall currents, medical technology devices, lamps, fuse boxes, WIFI related devices, televisions, medical electrical devices, automotive electric devices, telecommunications devices and electronic components in aircraft as well as harmonizing or clearing static electromagnetic frequency radiation that rebalances kinetic energy in the cells of a person's body.

### BRIEF DESCRIPTION OF THE DRAWINGS

The present invention will be described by way of exemplary embodiments, but not limitations, illustrated in the accompanying drawings in which like references denote similar elements, and in which:

FIG. 1 is an overhead perspective view of an electromagnetic frequency radiation for non-ionizing radiation harmonizer, in accordance with one embodiment of the present invention.

FIG. 2 is a flowchart for a method of utilizing an electromagnetic frequency radiation for non-ionizing radiation harmonizer, in accordance with one embodiment of the present invention.

### DETAILED DESCRIPTION OF ILLUSTRATIVE EMBODIMENTS

Various aspects of the illustrative embodiments will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative embodiments. However, it will be apparent to one skilled in the art that the present invention may be practiced without the specific details. In other instances, well-known features are omitted or simplified in order not to obscure the illustrative embodiments.

Various operations will be described as multiple discrete operations, in turn, in a manner that is most helpful in understanding the present invention however the order of description should not be construed as to imply that these operations are necessarily order dependent. In particular, these operations need not be performed in the order of presentation.

The phrase “in one embodiment” is used repeatedly. The phrase generally does not refer to the same embodiment, however, it may. The terms “comprising”, “having” and “including” are synonymous, unless the context dictates otherwise.

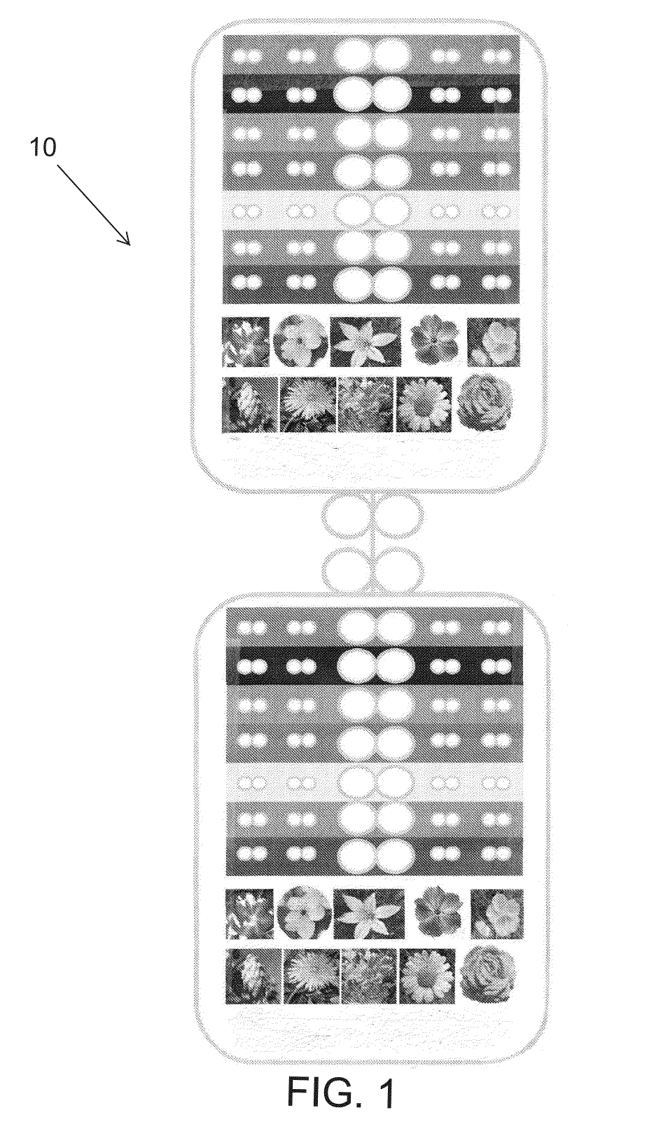

FIG. 1 is an overhead perspective view of an electromagnetic frequency radiation for non-ionizing radiation harmonizer 10, in accordance with one embodiment of the present invention. The electrons in healthy cells naturally spin freely in one direction. When the electrons of those healthy cells may be directly exposed to EMF radiation, such as when a cell phone may be against a person's ear (not shown), the exposed electrons spin changes from the EMF radiation frequencies. This unnatural spin reduces the cell's micro-voltage during the EMF radiation exposure time and long-term EMF radiation exposure has shown to produce a reduction of a healthy cell's overall energy, often resulting in various diseases such as cancer, chronic fatigue, fibromyalgia, impairment of cell apoptosis or cell death of abnormal tissue which may cause autism and other diseases.

The electromagnetic frequency radiation for non-ionizing radiation harmonizer 10 was made to help protect persons who may be exposed to levels of EMF radiation in their home and in convergence with EMF radiating devices. A problem with EMF radiation may be that the electrons from the EMF radiation spin backwards and knock the bio-rhythms of the healthy cells of a person's body out of sync, causing healthy cells of the body, especially the red blood cells, to clump or aggregate and their electrons to spin backwards also. The kinetic energy of the electrons of healthy cells typically spin forward and the backward spinning of the electrons of these healthy cells may de-mineralize these healthy cells causing disease, including but not limited to cancer, chronic fatigue, fibromyalgia, impairment of cell apoptosis or cell death of abnormal tissue, which may cause autism or other previously mentioned diseases.

The electromagnetic frequency radiation for non-ionizing radiation harmonizer 10 causes the EMF radiation to spin forward thereby allowing it to be in natural harmony with the biorhythm of the healthy cells of the body. It allows for a harmonization or mitigation of EMF radiation in non-ionizing EMF energized electronics, appliances and devices above approximately 0.0001 milli Gauss such as found in cell phones, household appliances, energized machinery, electrical wall currents, medical technology devices, lamps, fuse boxes, WIFI related devices, televisions, medical electrical devices, automotive electric devices, telecommunications devices and electronic components in aircraft. Multiple electromagnetic frequency radiation for non-ionizing radiation harmonizers 10 may be utilized to get the desired effects of harmonizing electromagnetic fields including but not limited to, cell phones, household appliances, energized machinery, electrical wall currents, medical technology devices, lamps, fuse boxes, WIFI related devices, televisions, medical electrical devices, automotive electric devices, telecommunications devices and electronic components in aircraft, as well as harmonizing or clearing static electromagnetic frequency radiation and rebalancing kinetic energy in the cells of the body.

The electromagnetic frequency radiation for non-ionizing radiation harmonizer 10 allows for the integration of vibrations or frequency mediums including colors, geometric shapes, flowers, plants, foods, water, stones, metal, music, videos, plastics and audio sounds that may be conducted through heat and chemical processing to potentiate textiles that include paper, fabric, plastics, metals or other suitable materials.

The thickness of the electromagnetic frequency radiation for non-ionizing radiation harmonizer 10 may range from a thin film of approximately one-one hundredth of an inch to approximately two inches, allowing for adaptation of virtually every type of suitable electronic device, including suitable cell phones, household appliances, energized machinery, electrical wall currents, medical technology devices, lamps, fuse boxes, WIFI related devices, televisions, medical electrical devices, automotive electric devices, telecommunications devices and electronic components in aircraft. The electromagnetic frequency radiation for non-ionizing radiation harmonizer 10 may be any length to adjust to any size of EMF radiation emitting electronic device. The electromagnetic frequency radiation for non-ionizing radiation harmonizer 10 may be in direct contact or be disposed within approximately one inch or more of any electronic device emitting EMF radiation that needs to be harmonized. The electromagnetic frequency radiation for non-ionizing radiation harmonizer 10 may be placed on a person's body and will harmonize static EMF radiation being exposed to that person's body. The electromagnetic frequency radiation for non-ionizing radiation harmonizer 10 may be utilized for cell phones, household appliances, energized machinery, electrical wall currents, medical technology devices, lamps, fuse boxes, WIFI related devices, televisions, medical electrical devices, automotive electric devices, telecommunications devices and electronic components in aircraft and other suitable devices that emit EMF radiation.

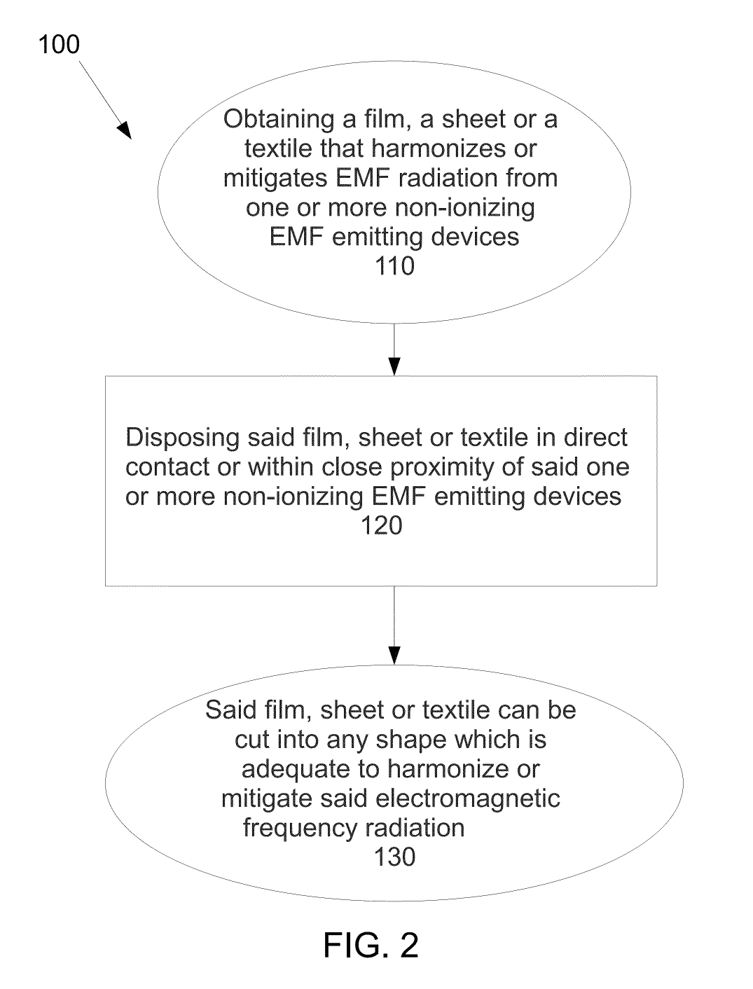

FIG. 2 is a flowchart illustrating a method for utilizing an electromagnetic frequency radiation for non-ionizing radiation harmonizer 100, in accordance with one embodiment of the present invention. The steps of the method for utilizing an electromagnetic frequency radiation for non-ionizing radiation harmonizer 100 include obtaining a film, a sheet or a textile that harmonizes or mitigates electromagnetic frequency or EMF radiation from one or more non-ionizing EMF emitting devices 110 and disposing the film, sheet or textile in direct contact or within dose proximity of one or more non-ionizing EMF emitting devices 120.

Use of the electromagnetic frequency radiation for non-ionizing radiation harmonizer may be straightforward. The electromagnetic frequency radiation for non-ionizing radiation harmonizer may be utilized in a variety of sizes from approximately one quarter inch and higher. The electromagnetic frequency radiation and non-ionizing radiation harmonizer may be in the form of plastic sheets approximately eight and one half inches by eleven inches, or any size film, sheet or textile that may also be cut into any size or shape which may be adequate for harmonizing the emitting EMF radiation that it may be placed on or in proximity to an object or person to be protected. For example an approximately half inch by three inch strip cut out of an approximately eight and one half by eleven plastic sheet of electromagnetic frequency radiation and non-ionizing radiation harmonizer may be adequate for protecting a user from EMF radiation from a cell phone. Other thicker electromagnetic frequency radiation for non-ionizing radiation harmonizer materials may also be utilized for higher exposures of EMF radiation above approximately 0.0001 milli Gauss such as suitable films, sheets and textiles.

The electromagnetic frequency radiation for non-ionizing radiation harmonizer has multiple applications ranging in dimensions from approximately one inch by one inch, two inches by two inches, ten inches by ten inches or any other suitable dimensions based on the amount of frequency to create bio-harmonics. The harmonizer utilizes nano technology and implements the principal of Mass-Energy Equivalence or E=MC2 in a process of digital inscripting to infuse frequency information that form “micro orberators” into plastic or film with various frequencies from hues of colors, water, flowers, plants, stones, herbs, vitamins, minerals and other natural energy mediums in a “manner” to make them interlock to create a vortex of energy powerful enough to impact the “atomic level” in electricity in both electrical currents, wireless systems and living matter, humans, animals and plants. Once the frequencies may be interlocked into the plastic or film, it becomes like a battery, than a colorful design may be applied to it for cosmetic appeal. There may be no function in the colorful design. If it may be washed or smudged off, the device will still work. It will hold the energy charge of the inscription for approximately three to eighteen months depending on the level of use. If left in the insulation packaging, it will hold the charged indefinitely. Control studies show technology samples that may be approximately four years old that may be still charged and functional to bio-harmonize cell phone radiation and balance the body on contact (FIGS. 1 and 2).

The technology may be revolutionary to reverse the molecular spin from a backward “unnatural spin” spin to a forward or “right” bio-balanced “natural spin” to sustain polarity or balance in humans, plants and animals as well as electricity and chemicals (FIG. 3). This may be measurable through MyoVision EMF Diagnotic Equipment that show static EMF radiation discharge and reduction in absorption in the body. Applied Kinetics: Muscle and BDORT Testing measurement show increased polarity and balance in the body in may be as where there has been imbalance when the body may be in contact with the technology. Dowsing instruments show reduced static radiation when the harmonizer may be placed on an electrical device. Magnetic Compasses that may be disoriented to magnetic north because of high electrical interference fields demonstrate corrected polarity and magnetic north orientation when the harmonizer may be placed on it.

### Bio Medical Observations Nerve Impulse Emulation

End users, doctors, parents and children's research center (The MiChi Health EpiCenter and The Cleveland Clinic) documents that the EMF harmonizer enhances nerve communication and impulse transmission on contact to support balance and polarity.

### Seizure Management

End users, doctors, parents and children's research center documents (The MiChi Health EpiCenter) that the EMF harmonizer stops “seizures” when in direct contact to the body and at the point where the seizure may be felt, instantly.

### Asthma Management

End users, doctors, parents and children research center documents (The MiChi Health EpiCenter, The Center for Equity in Health, Teachers College, Columbia University) show that the EMF harmonizer stops “asthma” attacks when utilized to energize water for less than approximately thirty seconds and the water may be drank.

### Weight Management

End users document (The MiChi Health EpiCenter) weight loss from approximately five pounds in one week to approximately one hundred and twenty five pounds in approximately one year from wearing the EMF Harmonizer on the left foot.

### Diabetic Management

End users document (The MiChi Health EpiCenter) rapid healing of retina bleeding in the eyes and resolve of approximately four years of blindness after wearing the EMF Harmonizer on the left foot and utilizing it may be as a color therapy light medium directly into eyes for approximately ten seconds each approximately three times daily.

### Wound Management

End users document (The MiChi Health EpiCenter) rapid healing of diabetic foot wounds in approximately four and one half months. These wounds would not heal in approximately eight years. End user utilizes EMF Harmonizers on the heel of left and right feet.

### Parkinson Management

End users document (The MiChi Health EpiCenter) the EMF Harmonizer on left and right heels or feet and in the left chest shirt pocket to stop Parkinson's tremors on within approximately three minutes.

### Sleep Management

End users report (The MiChi Health EpiCenter) the EMF Harmonizer placed on the bed or between the box springs and the mattress bio-balance the bed on contact. End users report reduced or elimination of insomnia and restlessness and restful sleep.

### Food Energetics

End users report (The MiChi Health EpiCenter) the EMF Harmonizer placed under food for above approximately three seconds increases energy in food. End users report increased energy after eating energized food.

### Balance Energetics

End users report (The MiChi Health EpiCenter) the EMF Harmonizer placed under the left foot balances the body on contact, temporarily. When removed imbalances will resume. However, if the water may be energized with the device for approximately ten seconds and all drunk imbalances in the body will remain balanced for approximately ten hours or more. This same phenomenal will occur when the EMF harmonizer may be placed on a flash light and placed on the body approximately two inches above the naval for approximately three minutes.

### Chemical Bio-Balance

Through additional research further discoveries have been made about the effectiveness of the EMF Harmonizer. Investigators have found that the device may also be utilized to change polarity in chemicals to bio-balance them and reduce their assault.

### Bleach

End users report that approximately one gallon of bleach creates imbalance when touched by the hand, externally. Then when a harmonizer may be applied for approximately thirty seconds, it may be bio-balanced. It will not imbalance the body when touched by the hand.

### Sanitary Pads

End users report that sanitary pads may be processed with chemicals that create imbalances when touched by the hand, externally. Then when a harmonizer may be applied for approximately one minute, it may be energized and bio-balance and will not imbalance the body when touched by hand.

### Cigarette Bio-Balance

End user reports that cigarettes create imbalance. She placed the cigarette on the EMF harmonizer for approximately one min to bio-balance it. She reports less coughing, chest tightness and pain during and after smoking a cigarette.

Different electrical, chemical systems require various amounts of frequencies interlocked to bio-balance, such as a cell phone or chemicals in a sanitary pad requires approximately fourteen or less frequencies where as a breaker box or chlorine bleach may require as many as forty-seven frequencies to get the results of bio-balancing to reduce the assault. But the technology may be engineered specifically to achieve bio-balance of the electrical current, chemicals, and polarity or balance in water, humans, plants and animals. In fact, the technology may be engineered specifically to the kinetic energy needs of the end users for optimal kinetic balance.

### Water Energetics

Many building codes in many cities direct electricity to be ground to a hot water tank or system. This process de-structures water and contributes to EMF radiation being in the water. These harmonizer technologies may be wrapped around the incoming water line and they will re-structure water in the whole house in less than approximately ten minutes. End user reports relief from stiff and pain and more subtle and soft skin from this application.

### Electrical and Mechanical Energetics

These nano technologies may be manufactured to decompose in fire and may be inflammable. Thus, they may be applied directly to the “hot wires and neutral wires” in breaker boxes in barns, residential and commercial buildings. In this application, they operate like “quasi processors” and slow down the molecular function to make electrical systems work more efficiently. End users report cost savings that exceed approximately fifteen percent on electrical bills, brighter lighting and reduction in noise in appliances.

### Scanning Energetics

Our laboratory testing of scanners utilized in grocery stores demonstrate that scanning devices cause imbalances and irradiation of water, produce, and other food sources regardless of the packaging in cans, plastic bags, etc. When the EMF Harmonizer may be applied to scanners, it bio-harmonizes the device to make it balance all the food sources, water, etc. and increase the energetics of the food.

### Cell Phone, IPAD®, Laptop, NOOK® and KINDLE® Energetics

In our laboratory and public education forums and screenings (The Cleveland Clinic and The MiChi Health EpiCenter) and testing of over approximately ten thousand, cell phones, tablet computers such as IPAD®, NOOK® and KINDLE, and laptop computers, approximately nine-hundred and ninety-nine people out of approximately one-thousand people will imbalance when touching these devices on contact. When an EMF Harmonizer may be applied to the cell phone, tablet computers such as IPAD®, NOOK® and KINDLE®, it causes the energetic of the device to bio-balance and none of the end users became imbalanced when touching the devices.

### Wireless Relay Communications for Farms

These nano technologies talk to each other. Thus, they may be excellent for logistical systems and may be being utilized on farms for monitoring devices. There was a problem where the monitoring system to register the cow was tazing the cows and creating imbalances. A custom system was made to turn the system into an energetic system which would energize the cow through the wireless collar that they wore which communicated to the logistics monitor. The end result may be a happier cow with a decrease incidents of mastitis, increased milk production per cow and a decreased incident of paralytic disease.

When two cell phones with the EMF harmonizer in them and may be linear in a line approximately fifty feet or more, they will link their bio-harmonics and bio-harmonize the space in between them and all electrical devices in that space.

### Wireless Applications

Another innovative benefit of the technology may be that in a “horizontal position” an approximate ten inch by ten inch square may create a vortex spin of bio-balance energy, mid-air, that may bio-harmonize all electrical devices and electrical wall systems from less than approximately two square feet to greater than approximately five-thousand square feet. This technology may help to stop these epidemics of diseases, especially autism.

While the present invention has been related in terms of the foregoing embodiments, those skilled in the art will recognize that the invention is not limited to the embodiments described. The present invention may be practiced with modification and alteration within the spirit and scope of the appended claims. Thus, the description is to be regarded as illustrative instead of restrictive on the present invention.

What is claimed is:

1. An electromagnetic frequency and non-ionizing radiation harmonizer, comprising:
a film, a sheet or a textile that harmonizes or mitigates EMF radiation from non-ionizing EMF emitting devices while allowing an integration of vibrations or frequency mediums from other sources.

2. The harmonizer according to claim 1, wherein said electromagnetic frequency radiation for non-ionizing radiation harmonizer harmonizes or mitigates said EMF radiation in non-ionizing EMF emitting devices above 0.0001 mille Gauss.

3. The harmonizer according to claim 2, wherein said non-ionizing EMF emitting devices include cell phones, household appliances, energized machinery, electrical wall currents, medical technology devices, lamps, fuse boxes, WIFI related devices, televisions, medical electrical devices, automotive electric devices, telecommunications devices and electronic components in aircraft.

4. The harmonizer according to claim 3, wherein said telephones include cell phones, cordless phones and land line phones.

5. The harmonizer according to claim 1, wherein said electromagnetic frequency and non-ionizing radiation harmonizer causes electrons of said EMF radiation to spin forward.

6. The harmonizer according to claim 1, wherein said electromagnetic frequency and non-ionizing radiation harmonizer harmonize or clear static electromagnetic frequency radiation.

7. The harmonizer according to claim 1, wherein said electrons of EMF radiation are in a natural harmony with a plurality of healthy cells of a person's body.

8. The harmonizer according to claim 1, wherein said electromagnetic frequency and non-ionizing radiation harmonizer range in thickness from less than one one-hundredth of an inch to two inches.

9. The harmonizer according to claim 1, wherein said other sources of vibrations or frequency mediums include colors, geometric shapes, flowers, plants, foods, water, stones, metal, music, videos, plastics and audio sounds that are conducted through heat and chemical processing.

10. A method of utilizing an electromagnetic frequency radiation and non-ionizing radiation harmonizer, comprising:
obtaining a film, a sheet or a textile that harmonizes or mitigates electromagnetic frequency radiation from one or more non-ionizing emitting devices; and
disposing said film, sheet or textile in direct contact or within dose proximity of said one or more non ionizing EMF emitting devices.

11. The method according to claim 10, wherein said film, sheet or textile are cut into any shape which is adequate to harmonize or mitigate said electromagnetic frequency radiation.

12. The method according to claim 10, wherein said electromagnetic frequency radiation and non-ionizing radiation harmonizer harmonizes or mitigates said EMF radiation in non-ionizing EMF emitting devices above 0.0001 milliGauss.

13. The method according to claim 12, wherein said electromagnetic frequency and non-ionizing radiation harmonizer causes said electrons of EMF radiation to spin forward.

14. The method according to claim 10, wherein said electrons of EMF radiation are in a natural harmony with a plurality of healthy cells of a person's body.

15. The method according to claim 10, wherein said non-ionizing EMF emitting devices include cell phones, household appliances, energized machinery, electrical wall currents, medical technology devices, lamps, fuse boxes, WIFI related devices, televisions, medical electrical devices, automotive electric devices, telecommunications devices and electronic components in aircraft.

16. The method according to claim 15, wherein said telephones include cell phones, cordless phones and land line phones.

17. The harmonizer according to claim 10, wherein said electromagnetic frequency and non-ionizing radiation harmonizer harmonize or clear static electromagnetic frequency radiation.

18. The method according to claim 10, wherein said electromagnetic frequency and non-ionizing radiation harmonizer range in thickness from a less than one one-hundredth of an inch to two inches.
